(19) United States
(12) Patent Application Publication
(10) Pub. No.: US 2008/0073646 A1
(43) Pub. Date: Mar. 27, 2008

(54) P-CHANNEL NANOCRYSTALLINE DIAMOND FIELD EFFECT TRANSISTOR

(75) Inventor: Adam H. Khan, Chicago, IL (US)

Correspondence Address: MARSHALL, GERSTEIN & BORUN LLP, 233 S. WACKER DRIVE, SUITE 6300, SEARS TOWER, CHICAGO, IL, 60606, US

(73) Assignee: AKHAN TECHNOLOGIES,INC., Schaumburg, IL (US)

(21) Appl. No.: 11/838,100

(22) Filed: Aug. 13, 2007

Related U.S. Application Data
(60) Provisional application No. 60/837,014, filed on Aug. 11, 2006.

(51) Int. Cl. H01L 29/04; H01L 21/04

(52) U.S. Cl. 257/64; 438/105; 257/E29.003; 257/E21.051

(57) ABSTRACT

An electrically conducting p-channel diamond lattice field effect transistor (DLFET) composed of nanocrystalline diamond having at least about 10²⁰ atoms/cm³ of boron in conduction channel is disclosed, along with methods of making the same. The nanocrystalline diamond may be characterized by having an average grain size diameter of less than 1 μm, and in particular, grain sizes on the order of 10 to 20 nm, for improved performance of the DLFET.

### CROSS-REFERENCE TO RELATED APPLICATIONS

This application claims the benefit of U.S. Provisional Application No. 60/837,014, filed Aug. 11, 2006, which is incorporated by reference in its entirety herein.

### FIELD OF THE INVENTION

The application generally relates to techniques for forming semiconductor circuit elements and more particularly to techniques for forming circuit elements of a doped diamond layer

### BACKGROUND OF THE INVENTION

The use of diamond as suitable electronic material has been out of reach for many years. The problems lie in both the diamond itself, whether synthetic or natural, and in the methods used to treat the diamond. It has been particularly difficult, for example, to form diamond so that its ambient temperature conductivity and carrier mobility are sufficiently high to make diamond-based devices work at ambient or room temperatures.

Methods for processing and producing diamond-based power RF (Radio Frequency) FETs (Field Effect Transistor) have been proposed. The superior thermal conductivity and the high breakdown voltage make diamond attractive for high power electronics. Unfortunately, up to now, no technically relevant donor is available. Therefore, all devices demonstrated up to now have been based on p-type conductivity originated from a hydrogen surface termination (which causes a very thin conducting layer at the diamond surface originating from a shallow acceptor state, which is still chemically unidentified). Therefore, the active channel of diamond FETs have been previously realized by a hydrogen surface termination. Nevertheless, due to the fact that the channel is located at the surface and the stability of the H-induced acceptor level is still in question the transistor characteristics are not stable and large signal and power performance have not been reported. Furthermore, such methods have either focused on single crystalline diamond, which has poor carrier mobility characteristics and limited gain profiles, or polycrystalline diamond of grain sizes too large for the currently desired transistor sizes and grain sizes also of limited carrier mobility.

### SUMMARY

In part response to the shortcoming of the prior art, the present application provides devices that are constructed using polycrystalline diamond having a nanometer size grain and with doped thin film layers having sizes on the order of less than 100 nm. The techniques for forming such structures may be used to form Radio Frequency (RF) FET devices having diamond grain boundaries that are almost atomically abrupt (−0.5 nm), thereby allowing for more uniformity of electrical performance, as well as the ability to form thin-film features. The RF FET devices exhibit exceptional electronic, thermal and RF properties, the first particularly applicable to the development of new Power Discrete devices. The present application in particular provides methods of fabricating such an RF FET device using nanometer and sub-nanometer polycrystalline diamond, e.g., diamond films having an average grain size of up to about 100 nm.

Accordingly, various techniques described herein provide an electrically conducting nanocrystalline P-Channel diamond lattice field effect transistor (FET) having a dopant concentration of at least about 10²⁰ atoms/cm³ (also noted a E 20 atoms/cm³) boron in a conducting channel of the transistor. In some embodiments, the dopant concentration is E 21 atoms/cm³ or greater, E 22 atoms/cm³ or greater, E 23 atoms/cm³ or greater, E 24 atoms/cm³ or greater, and E 25 atoms/cm³ or greater. In some embodiments, the grain size of the nanocrystalline diamond is between about 1 nm to about 15 nm. In various embodiments, the resulting radio frequency output power at about 25° C. may be at least about 1 W/mm, in particular at least about 10 W/mm, and in some examples at least about 20 W/mm.

Various techniques include doping a nanocrystalline diamond with boron such that the boron has a concentration of at least about 10²⁰ atoms/cm³ in a conducting channel of the transistor. This doping, for example, may be carried out at a temperature up to about 77 K, and, also by way of example, through an ion implantation process. In some examples, the ion implantation can be performed using MeV energy sources, typically about 1 MeV to about 20 MeV. In various examples, the method further comprises annealing the diamond, where that annealing can be performed on a diamond substrate grown as a thin film. In some examples, this annealing process may be achieved using laser processing while in other examples the annealing may be achieved by high pressure high temperature annealing. In embodiments using laser processing, the laser may be a Q-switched laser or a YAG laser, and the laser processing can comprise pulsing with the laser for between about 1 nanosecond (ns) to about 50 ns. In embodiments using high pressure high temperature annealing, the annealing can be performed in a graphite heater and/or with a cubic anvil-type high pressure apparatus. In some specific cases, the film substrate is encased in a block of sodium chloride. The method may further comprise isolating the transistor using a chemical oxygen treatment, such as contacting the transistor with an acid solution, such as sulfuric acid, nitric acid, or a mixture thereof. In some embodiments, the method further comprises defining at least one ohmic contact by masking the transistor through photolithography, where that ohmic contact may comprise a metal such as nickel, gold, or mixtures thereof. In various embodiments, the method may further include etching a recessed gate into the transistor, through an ion etching or other process, and forming the gate to include an n-type buffer region formed of aluminum or another n-type dopant.

The invention consists of certain novel features and a combination of parts hereinafter fully described, illustrated in the accompanying drawings, and particularly pointed out in the appended claims, it being understood that various changes in the details may be made without departing from the spirit, or sacrificing any of the advantages of the present invention.

### BRIEF DESCRIPTION OF THE DRAWINGS

For the purpose of facilitating an understanding of the invention, there is illustrated in the accompanying drawings a preferred embodiment thereof, from an inspection of which, when considered in connection with the following description, the invention, its construction and operation, and many of its advantages should be readily understood and appreciated.

FIGS. 1 and 2 show top and partial side views, respectively, of an example electrical device (e.g., transistor) formed with of a heavily doped p-channel diamond region in accordance with an example herein.

FIG. 3 shows the phase diagram of carbon at various temperatures and pressures, where the hatched area shows the preferred range of pressures and A, B, and C indicate the temperatures at which the carbon exists as diamond, graphite, and liquid, respectively, at these operating pressures.

FIG. 4 illustrates a plot of the RF characteristics of transistor having a p-channel diamond region in accordance with an example herein, where MAG is maximum available gain and MUG is maximum unilateral gain.

FIG. 5 illustrates is a graph of the drain current vs. drain voltage of a transistor having a p-channel diamond region in accordance with an example herein.

FIG. 6 illustrates a plot of the RF gain versus source RF frequency for a transistor having a p-channel diamond region in accordance with an example herein.

### DETAILED DESCRIPTION

Traditionally, diamond has been virtually untapped in terms of its potential within the Wide Band Gap (WBG) semiconductor market. Table 1 illustrates diamond's potential as compared to other semiconductor platforms (Ozpineci, et al., Comparison of Wide Band Gap Semiconductors for Power Electronics Applications,” Doc. No. ORNL/TM-2003/257, Dec. 12, 2003, Department of Energy Report available at www.ntis.gov/support/ordernowabout.htm). Across all the fields diamond had higher figures of merit, and in some by orders of magnitude. The present application describes techniques for using a diamond as a platform for unipolar device platforms (i.e. FETs), and extending such uses to into other electrical, semiconducting devices.

TABLE 1

| | Si | GaAs | 6H—SiC | 4H—SiC | GaN | Diamond |
|---|---|---|---|---|---|---|
| JFM | 1 | 1.8 | 277.8 | 215.1 | 215.1 | 81,000 |
| BFM | 1 | 14.8 | 125.3 | 223.1 | 186.7 | 25,106 |
| FSFM | 1 | 11.4 | 30.5 | 61.2 | 65 | 3,595 |
| BSFM | 1 | 1.6 | 13.1 | 12.9 | 52.5 | 2,402 |
| FPFM | 1 | 3.6 | 48.3 | 56 | 30.4 | 1,476 |
| FTFM | 1 | 40.7 | 1470.50 | 3,424.80 | 1,973.60 | 5,304,459 |
| BPFM | 1 | 0.9 | 57.3 | 35.4 | 10.7 | 594 |
| BTFM | 1 | 1.4 | 748.9 | 458.1 | 560.5 | 1,426,711 |

JFM—Johnson's Figure of Merit (Measure of Ultimate High Frequency Capability)
BFM—Baliga's Figure of Merit (Measure of on-state resistance)
FSFM—FET Switching Speed Figure of Merit
BSFM—Bipolar Switching Speed Figure of Merit
FPFM—FET Power Handling Figure of Merit
FTFM—FET Power Switching Product Figure of Merit
BPFM—Bipolar Power Handling Capacity Figure of Merit

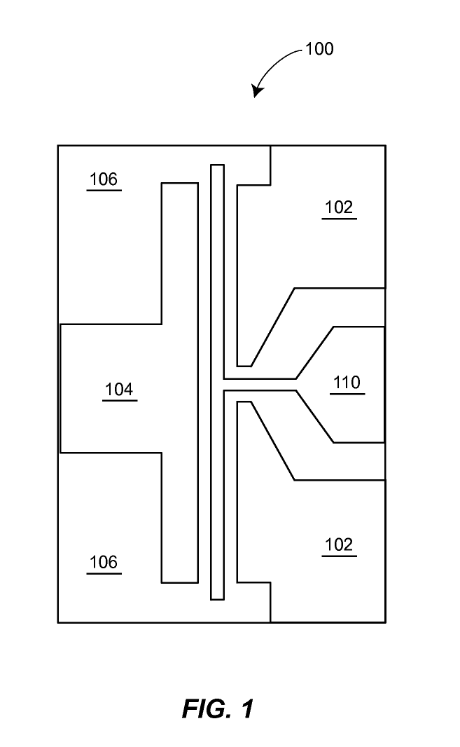

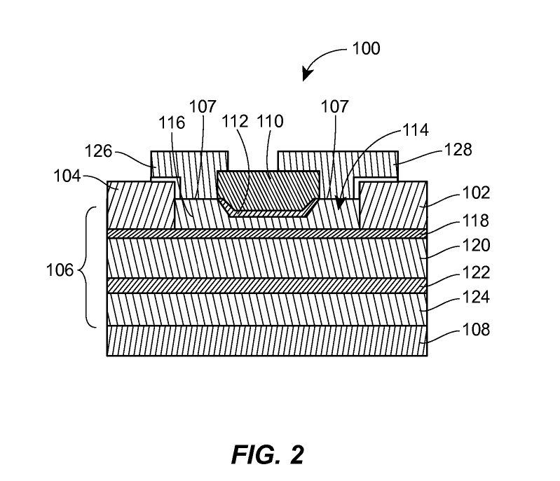

FIG. 1 illustrates a top view of a FET 100 formed of a high-dopant concentration diamond carrier channel extending between a source 102 and drain 104. The high dopant channel is formed in a diamond substrate 106, shown in top view in FIG. 1 and in a front view in FIG. 2 which shows the multiple layers forming the diamond substrate 106. The diamond substrate 106 is formed on a growth wafer 108, which may be formed of low-loss dielectric material, such as quartz, vicor, Pyrex, SiC, fused silica, or the like. The polycrystalline diamond substrate 106 may be deposited on the wafer 108. This deposition on a n-type low loss material allows for improved RF performance (e.g., low leakage) and provides a barrier layer for the transistor. A low loss material is a material with a low loss tangent and a dielectric loss less than that of silicon.

The source 102 and drain 104 may be formed of gold (Au) or other suitable metal and extend below the upper surface of the diamond substrate 106 into recessed portions thereof, as shown. A gate 110, also formed of aluminum (Al) also extends below the upper surface of the diamond substrate 106 and into a recess. The gate 110 includes a lower portion 112 that has been lightly doped with an n-type impurity such as aluminum nitride (AlₓN_{y}), to form a buffer region protecting against bleed over of the carriers in a p-channel region 114 extending between the source 102 and drain 104.

The diamond substrate 106 is a multilayered structure including a first intrinsic (undoped) diamond region 116 above a heavily doped region 118, also termed a delta channel, which includes high concentration Boron atoms, e.g., on the order of E 20 Boron atoms/cm³ (10²⁰ B atoms/cm³) to E 25 Boron atoms/cm³ or greater, in accordance with techniques discussed below. The region 118 is a thin film layer, for example, of approximately 3-4 nm thick, that may be formed by annealing a nanometer grain sized, polycrystalline diamond material. Another intrinsic diamond region 120 extends below the region 118, between the region 118 and a nitrogen-doped shield region 122 that acts as another buffer against current tunneling through to the wafer substrate 108. The shield region 122 extends above another intrinsic diamond region 124 that has been grown directly on the substrate 108. The shield region 122 may, like the other layers forming the diamond substrate 106, have a thickness in a nanometer scale, i.e., below 1 μm. In an example, and for a doped region on the order of 3-4 nm, the shield region 122 may have a thickness on the order of 150 nm. The shield region 122 comprises aluminum, and can further comprise an n-type impurity, such as nitrogen.

The doped region 118 is a polycrystalline diamond that can have a grain size up to 100 nm. Preferably, however, a grain size of about 10 nm to about 20 nm, or about 15 nm is used, although grain sizes even as low as 1 nm may be used in some circumstances. A transistor like that of the FET 100 and formed of pure diamond (i.e., no graphitic phases) conceptually could be susceptible of parasitics, instabilities, and degradation if in a larger grain size form or monocrystalline form. By controlling the grain boundary size, the inventors have found that better DC performance of the device can be achieved.

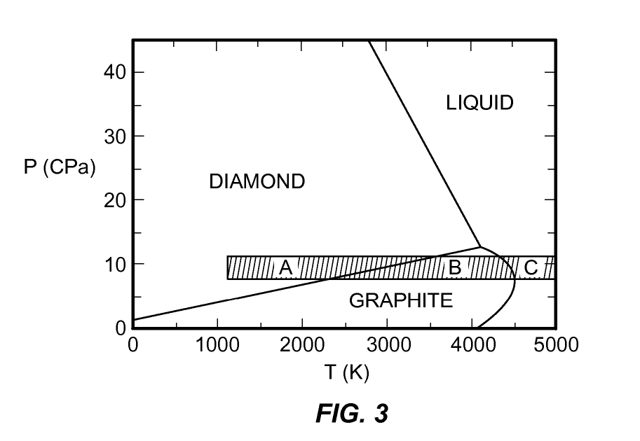

After growth of the initial diamond layer, intrinsic region 124, and doping of the shield region is achieved, the region 118 is formed through doping an upper portion of the region 120, with boron. Several ion deposition techniques can be used. Typically, an impeding step towards useful diamond-based electronic devices is the ability to controllably and reproducibly dope the diamond. Ion implantation can be used to precisely control the dopant concentration and allow for spatially selective doping via standard masking techniques. Thermal annealing can also be used in combination with the implantation, although attention should be paid such that undesirable relaxation of the diamond to graphite does not occur. FIG. 3, in fact, illustrates the phase diagram of carbon, showing the forms carbon takes at various temperatures and pressures. For purposes of the disclosed invention, it is desired to maintain the carbon in the diamond state, without relaxing to graphite. Thus, monitoring of the temperature at the pressures in which the devices are prepared is important (see the shaded area, where the area marked “A” is the desired range of temperatures and pressure, while “B” is the undesired relaxation to graphite).

The diamond layer extending above the shield 122 (and which after doping will form the layers 118 and 120) can be implanted with low MeV singly charged boron ions or another suitable dopant, to provide a dose of E 15 ions/cm². Calculations using a TRIM Monte Carlo simulation software predict that the peak vacancy concentration produced by such a dose would be E 21 vacancies/cm³, which is just below the critical dose which would be needed to amorphize the diamond. Such a doping protocol provides a boron-doped layer, typically about 3-4 nm thick, buried about 75 nm below the upper surface of diamond substrate 106 in which the maximum boron concentration is about E 20 B atoms/cm³ as measured by SIMS (Secondary Ion Mass Spectrometry), which is a surface and thin film analysis technique used to characterize trace and major elements on solid surfaces. Concentrations of the boron dopant in the region 118 may be E 21 atoms/cm³ or greater, E 22 atoms/cm³ or greater, E 23 atoms/cm³ or greater, E 24 atoms/cm³ or greater, and E 25 atoms/cm³ or greater. Since carrier activation energies of boron in diamond decrease as dosage increases, the dosage used in the methods herein are sufficiently high that the energies are negligible. The implantation is typically performed at a temperature up to about 77K, as this temperature corresponds to the critical temperature in diamond which immobilizes traps, holes, and instabilities, and the implantation is performed through a custom mask, and as it facilitates Hall measurements and produces an intrinsic diamond cap layer on the same diamond. Full carrier activation is obtained due to the high dosage of boron in the narrow profile size of the region 118. It is believed that the boron atoms within the profile are confined and are forced to form mini-bands, which aid in successful propagation across the resulting channel. This result can also be achieved using boron chemical absorbents during the growth of the diamond wafer to obtain an intrinsic cap layer.

Annealing of the diamond region 118 can be performed using two approaches: laser irradiation or high-pressure high temperature (HPHT) annealing. Laser irradiation can be done using a Q-switched laser, or more specifically a frequency doubled YAG pulsed laser. The diamond is selectively treated by a high energy (about 800 keV to about 1.4 MeV) density nanosecond laser pulse (about 532 nm). The laser pulse is selectively absorbed in the diamond at the end of the range and the temperature of the diamond is raised sufficiently to melt the diamond. The melt front propagates to the surface of the transistor, relieving the internal pressure and preventing the diamond from relaxing to graphite. Full carrier activation can be achieved with channel mobilities of at least about 1000 cm²/Vs.

High-pressure high temperature (HPHT) annealing can be performed on the polycrystalline diamond having an area of up to about 3.6 mm² and a thickness of up to about 2 μm. To perform HPHT, the diamond is encased in a sodium chloride block, in a graphite heater, using a cubic-anvil-type high pressure apparatus. Conditions for this encasement involve exposing the diamond to a pressure of about 6 GPa and a temperature of about 1200° C. for about one hour. At this pressure and temperature the diamond is still within the thermodynamically stable region of diamond as seen in FIG. 1. Under such conditions, free excitation emission at ambient temperatures is almost doubled, and ambient mobility post-anneal is typically 1042 cm²/V s.

The upper surface of the diamond substrate 106 may experience passivation and termination problems, that if not dealt with properly, may decrease device lifetime and function. Therefore, the upper surface of the diamond substrate 106, i.e., the exposed regions 107 on either side of the gate 110 have formed thereon a passivation layer (not shown) to protect against contamination. The surface-passivation layer should sustain a higher or at least equally high breakdown field as compared to diamond. Electrical isolation can be obtained by local oxygen termination, this achieved surface potential pinning at 1.7 eV above the valence band edge and an associated surface depletion. Exposure of the diamond surface to a sulfuric and nitric acid solution at 200° C. for approximately 15 minutes can be used to achieve oxygen termination on the upper surface. The amount of oxygen absorbed can be monitored to prevent formation of dipoles.

For the ohmic contacts of the gate 110, source 102 and drain 104, standard etching and photolithography schemes may be implemented. Source and drain contacts may be achieved by gold metallization through a standard shadow mask. The electrodes may be characterized in a solution comprising of both sulfuric acid and potassium hydroxide aqueous solutions. The design may be modified to make use of the laser irradiation/processing to create graphite columns tunneling from both source and drain to the FET channel. This can improve the DC results, as the resistances would drop respective to each component.

Three specific unique functions were incorporated in one example design with respect to the gate 110: the gate 110 is recessed; the partially n-type buffer region 112 is used; and field plates 126 and 128 (not shown in FIG. 2) are used. The first of these functions, being the recessed gate allows the design to avoid parasitic current limiters outside of the gate region via the free surface potential and to fully exploit the enhancement mode of operation. First the gate area of the diamond region 116 was etched via electron beam lithography, then the recess was achieved using reactive ion etching which resulted in a recess of about 30 nm. To obtain the maximum RF power density, a combination of gate parameters and sheet charge density was employed. The machinery used to measure the RF aspects is an on-wafer test bench. By using the specific combination of parameters, such as, e.g., sheet charge density, gate length, and the like, maximum RF power density may be obtained. Thus, variable solutions to the matrix involving sheet charge density, gate length, and geometrical dimensions of the gate field plate and recess were implemented. The gate metallization was achieved by electron beam evaporation of aluminum and structured via electron-beam lithography. The gate width (along the y-axis of FIG. 1) was approximately 50 μm and the gate length (along the x-axis of FIG. 1) was approximately 100 nm. Next, the gate metal was treated with nitrogen doping to produce a gate barrier within the device. Though not fully activated at room temperature, the gate still obtained its desired result of dielectric barrier. Finally, to eliminate parasitic capacitance and the high field region associated with the gate 110, incorporation of both three-dimensional shaping and the use field plates was warranted. This was achieved through an overlap metallization. The field plate 126 extending 1 μm toward the drain 104 and the field plate 128 extending 1 μm toward the sources 102 enabled relaxation of electrical field within the gate recess area, such that breakdown occurred at a much higher drain bias than that associated with a planar structure. The high field plates 126 and 128 may be formed of Al and mounted to the upper surface of the diamond substrate 106 adjacent the gate 110 and over a portion of the p-channel 114.

The output characteristics are detailed graphically in the accompanying illustrations. The figures of interest are as follows: the RF power output, maximum drain voltage, and maximum drain current are approximately 26.7 W/mm at approximately 1 GHz, −127 V, and −1.8 A/mm, respectively, at a gate voltage of −4 V. The small signal sweep ranged from 1 GHz to 81 GHz under class A operation. This range may be increased by decreasing the grain size of the substrate even further as to allow for better wave propagation. The grain size is a property of the material used. Surface potential and DC characterization measurements were done by AFM Kelvin Probe Microscopy. The RF measurements were done by an on-wafer test bench.

### EXAMPLES

Boron-doped P-channel nanocrystalline diamond FETs have been produced using a novel approach on several existing methods. In an example implementation, a synthetic diamond provided by Advanced Diamond Technologies, Inc. (Argonne, Ill.) was used. Specifically, the UNCD (Ultra Nano Crystalline Diamond) Aqua 100 (grain size approximately 25 nm) was chosen for its mechanical and electrical properties being so similar to natural diamond. Further, this diamond film is among the highest in phase purity (no graphitic phases). After diamond growth, the next step was to define the different areas within the diamond. The first area to be defined was a 50 nm buffer layer (similar to that of layer 122). This layer was formed through high-energy (2.1 MeV) ion implantation of the diamond at 77 K, with a dosage of nitrogen at 1.8 E 16/cm³. In a second step, the boron doped channel layer was formed via ion implantation, using a considerably higher concentration (Na>>10²⁰, doping profile<5 nm), at an ion energy of 1.1 MeV. Thus remaining on top of the channel was a 50 nm thick undoped cap layer. The samples were annealed via laser processing, which prevented any relaxation of the diamond to graphite, and ensured full activation of the acceptors and partial donor activation. Processing was done by high energy density nanosecond laser pulses (532 nm) using a Q-switched, frequency doubled Nd:YAG pulsed laser. After cleaning the samples, the gate area was defined by electron-beam lithography and a recess was etched by RIE (about. 30 nm deep). Finally, the contact metallization (Au) was deposited by electron beam evaporation and structured by conventional lithography (source, drain) and electron beam lithography (gate). Next, incorporation of the gate field plate was necessary and was done via the same means as the gate itself. A field plate enables the relaxation of the electrical field within the gate recess area, such that breakdown will occur at a much higher drain bias. The efficiency of the field relaxation can be influenced by the length of the field plate. For the case of plate length equal to 1 μm the maximum RF power observed was approximately 27 W/mm. By increasing this gate length, the power handling capability of the device should reach its thermal limit. However, by extending the field plate, the parasitic field plate capacitance may increase. Since the dielectric constant of diamond is lower than that of other wide bandgap semiconductors (e.g., GaN), the effect of the parasitic field plate capacitance on the RF performance of diamond based FET structures is lower than that of GaN based devices with similar configuration.

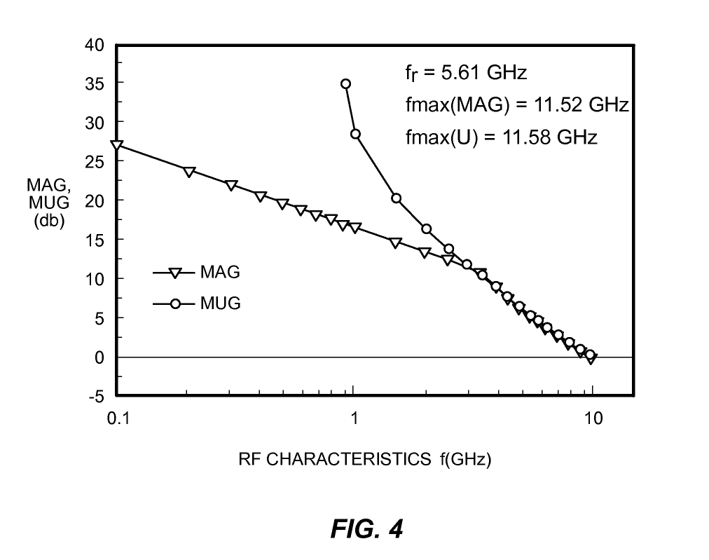

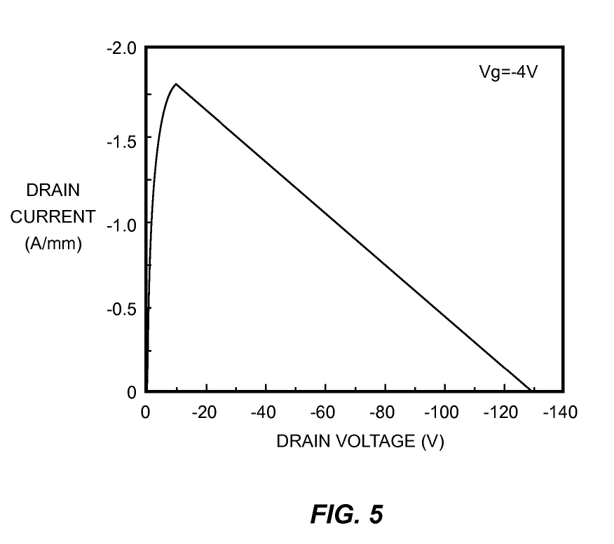

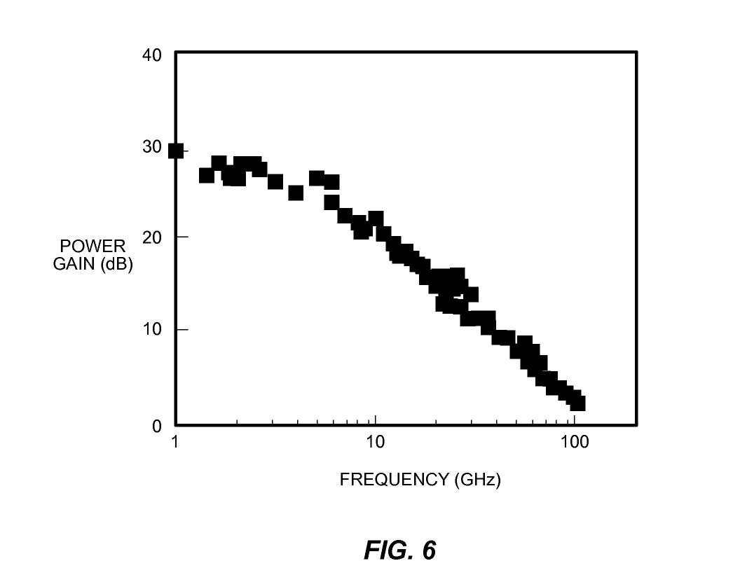

To obtain the cut-off frequency and the maximum frequency of oscillation both for the maximum available gain (MAG) and the maximum unilateral gain (MUG), small signal parameter (S-parameter) measurements were performed on the resulting structure. The results can be seen in FIG. 4, which shows the measured MAG and MUG versus frequency. FIG. 4 shows the RF gain plots of current gain and maximum power gain over a range of frequencies. The extracted cutoff frequencies fr and fmax were slightly above 1 GHz, where fr is the class A operation bias point, that is the point at which the device signal outputs during class A operation. In FIG. 5, output characteristics of the device are shown for different drain voltages under a gate voltage of −4 V. The maximum drain current, Id, 1.8 A/mm, and the maximum drain voltage, V_{d}, is 127 V. Finally, in FIG. 6, a power sweep is illustrated showing the power gain measured from the on-wafer test bench for RF data power information, which was obtained at 1 GHz for small signal measurements for class A operation.

Of course, while the application discusses examples in the context of a FET, it will be appreciated that the present techniques describe heavily impurity doped nanocystralline diamond layers that may be used in another electrical devices, including diodes and other switches, and are not limited to the specific implementations shown herein.

While particular embodiments of the present invention have been shown and described, it will be appreciated by those skilled in the art that changes and modifications may be made without departing from the invention in its broader aspects. Therefore, the aim in the appended claims is to cover all such changes and modifications as fall within the true spirit and scope of the invention. The matter set forth in the foregoing description and accompanying drawings is offered by way of illustration only and not as a limitation. The actual scope of the invention is intended to be defined in the following claims when viewed in their proper perspective based on the prior art.

What is claimed:

1. A field effect transistor comprising a polycrystalline diamond conducting channel doped with boron having a concentration of at least about 10²⁰ atoms/cm³, wherein the polycrystalline diamond conducting channel has an average grain size below 1 μm.

2. The transistor of claim 1, wherein the nanocrystalline diamond has an average grain size up to about 100 nm.

3. The transistor of claim 1, wherein the nanocrystalline diamond is disposed on low loss dielectric material substrate.

4. The transistor of claim 1, having a radio frequency (RF) output power at about 25° C. of at least about 1 W/mm.

5. The transistor of claim 4, having a RF output power of at least about 10 W/mm.

6. The transistor of claim 4, having a RF output power of at least about 20 W/mm.

7. The transistor of claim 1, wherein the boron concentration in the polycrystalline diamond conducting channel is at least about 10²¹ atoms/cm³.

8. The transistor of claim 1, wherein the boron concentration in the polycrystalline diamond conducting channel is at least about 10²² atoms/cm³.

9. The transistor of claim 1, wherein the boron concentration in the polycrystalline diamond conducting channel is at least about 10²³ atoms/cm³.

10. The transistor of claim 1, further comprising:
a first intrinsic diamond layer;
a shield layer formed of aluminum doped with an n-type impurity;
a second intrinsic diamond layer; and
a third intrinsic diamond layer, with the polycrystalline diamond conducting channel being disposed between the second and third intrinsic diamond layers.

11. The transistor of claim 10, further comprising:
a gate electrode;
a source electrode: and
a drain electrode, where at least one of the gate electrode, source electrode, and drain electrode are disposed

12. A method of manufacturing a nanocrystalline P-channel diamond lattice field effect transistor, the method comprising:
doping a nanocrystalline diamond region with boron to form the nanocrystalline P-channel diamond lattice region extending between a source and drain of the field effect transistor and below a transistor gate, wherein the boron in the nanocrystalline P-channel diamond lattice region has a concentration of at least about 10²⁰ atoms/cm³, and wherein the doping comprises ion implantation.

13. The method of claim 12, wherein the nanocrystalline diamond region is a thin film.

14. The method of claim 12, wherein the ion implantation comprises using a deposition energy of at least about 1 MeV.

15. The method of claim 12, wherein the doping is conducted at a temperature up to about 77K.

16. The method of claim 12, further comprising annealing the nanocrystalline P-channel diamond lattice region.

17. The method of claim 16, wherein the annealing comprises laser processing the nanocrystalline diamond region.

18. The method of claim 17, wherein the laser processing uses a Q-switched laser.

19. The method of claim 17, wherein the laser processing uses a YAG laser.

20. The method of claim 17, wherein the laser processing comprises pulsing the laser for pulses of 1 nanosecond to about 10 nanoseconds.

21. The method of claim 16, wherein the annealing comprises applying a high pressure high temperature annealing.

22. The method of claim 21, wherein nanocrystalline diamond region comprises a film substrate.

23. The method of claim 22, wherein the film substrate is encased in sodium chloride.

24. The method of claim 21, wherein the annealing further comprises using a graphite heater.

25. The method of claim 21, wherein the high pressure high temperature annealing comprises using a cubic-anvil-type high-pressure apparatus.

26. The method of claim 12, further comprising isolating the transistor using a chemical oxygen treatment.

27. The method of claim 26, wherein the chemical oxygen treatment comprises contacting the transistor with an acid solution.

28. The method of claim 27, wherein the acidic solution comprises sulfuric acid, nitric acid, or a mixture thereof.

29. The method of claim 12, further comprising defining at least one ohmic contact by masking the transistor using photolithography.

30. The method of claim 29, wherein the ohmic contact comprises a metal selected from the group consisting of gold, nickel, and mixtures thereof.

31. The method of claim 12, further comprising etching the gate into the transistor, wherein the gate is recessed.

32. The method of claim 31, wherein the etching comprises reactive ion etching.

33. The method of claim 31, wherein the gate comprises n-type aluminum.

34. The method of claim 33, further comprising using nitrogen to deposit the n-type aluminum.
